(19) United States
(12) Patent Application Publication
(10) Pub. No.: US 2026/0110720 A1
(43) Pub. Date: Apr. 23, 2026

(54) MEASUREMENT CIRCUIT

(71) Applicant: Murata Manufacturing Co., Ltd., Nagaokakyo-shi (JP)

(72) Inventors: Yoshie KURAMOCHI, Nagaokakyo-shi (JP); Yu TAKEHARA, Nagaokakyo-shi (JP); Shin HASEGAWA, Nagaokakyo-shi (JP)

(21) Appl. No.: 19/428,429

(22) Filed: Dec. 22, 2025

Related U.S. Application Data
(63) Continuation of application No. PCT/JP2024/019732, filed on May 29, 2024.

(30) Foreign Application Priority Data
Aug. 14, 2023 (JP) 2023-131884

(51) Int. Cl. G01R 27/08

(52) U.S. Cl. CPC G01R 27/08

(57) ABSTRACT

A measurement circuit includes a resistive element array including m first lines, n second lines, and a plurality of measurement resistive elements connected between the m first lines and the n second lines where m×n≥2; a voltage control circuit controlling a voltage of an output terminal by an operational amplifier located between an input terminal connected to a first connection line to which a constant current is supplied from a constant current source and the output terminal so that a difference between a voltage of the input terminal and the voltage of the output terminal is reduced; and a selection circuit connecting one of the m first lines to the first connection line, connecting one of the n second lines to a second connection line connected to ground, and connecting remaining lines among the m first lines and the n second lines to the output terminal.

### CROSS REFERENCE TO RELATED APPLICATION

This is a continuation of International Application No. PCT/JP2024/019732 filed on May 29, 2024 which claims priority from Japanese Patent Application No. 2023-131884 filed on Aug. 14, 2023. The contents of these applications are incorporated herein by reference in their entireties.

### BACKGROUND OF THE DISCLOSURE

### Field of the Disclosure

The present disclosure relates to a measurement circuit.

### Description of the Related Art

Japanese Unexamined Patent Application Publication No. 2020-34514 discloses a resistive element array circuit. The resistive element array circuit includes a plurality of word lines, a plurality of bit lines, a plurality of resistive elements, a selecting unit, a difference amplifier, and an earth terminal. The plurality of word lines are connected to a power source. The plurality of resistive elements are arranged at a plurality of intersections of the plurality of word lines and the plurality of bit lines. The selecting unit selects any one word line and selects any one bit line. The difference amplifier includes a positive input terminal to which the selected bit line selected by the selecting unit among the plurality of bit lines is connected, a negative input terminal connected to both of a non-selected bit line that has not been selected by the selecting unit among the plurality of bit lines and a non-selected word line that has not been selected by the selecting unit among the plurality of word lines, and an output terminal connected to the negative input terminal. The earth terminal is connected to the positive input terminal.

### BRIEF SUMMARY OF THE DISCLOSURE

In the resistive element array circuit (measurement circuit) disclosed in Japanese Unexamined Patent Application Publication No. 2020-34514, the power source is a constant voltage source, which leads to poor noise immunity. In a case where the power source is a constant voltage source, a current flowing through a resistive element itself changes due to a change of a resistance value of the resistive element. This may cause a change in amount of self-heating, thereby affecting measurement accuracy.

The present disclosure provides a measurement circuit that can improve noise immunity and measurement accuracy.

A measurement circuit according to the aspect of the present disclosure includes a resistive element array including m first lines, n second lines, and a plurality of measurement resistive elements connected between the m first lines and the n second lines where m×n≥2; a voltage control circuit including an input terminal connected to a first connection line to which a constant current is supplied from a constant current source, an output terminal, and an operational amplifier and/or a transistor located between the input terminal and the output terminal, and controls a voltage of the output terminal by the operational amplifier and/or the transistor so that a difference between a voltage of the input terminal and the voltage of the output terminal is reduced; and a selection circuit that connects one of the m first lines to the first connection line, connects one of the n second lines to a second connection line connected to ground, and connects remaining lines among the m first lines and the n second lines to the output terminal, and is thereby capable of selecting a measurement resistive element to which the constant current is supplied from among the plurality of measurement resistive elements.

The aspect of the present disclosure makes it possible to improve noise immunity and measurement accuracy.

### BRIEF DESCRIPTION OF THE SEVERAL VIEWS OF THE DRAWINGS

FIG. 1 is a schematic circuit diagram of a measurement circuit according to Embodiment 1.

FIG. 2 is an explanatory view for explaining an example of currents flowing through a measurement circuit according to Embodiment 1.

FIG. 3 is a graph illustrating an example of resistance value-temperature characteristics of a measurement resistive element.

FIG. 4 is a graph illustrating a result of evaluation of the measurement circuit according to Embodiment 1.

FIG. 5 is a schematic circuit diagram of a measurement circuit according to Embodiment 2.

FIG. 6 is an explanatory view for explaining an example of currents flowing through the measurement circuit according to Embodiment 2.

FIG. 7 is a graph showing an error of a difference between a voltage of a first connection line and a voltage of a second connection line with respect to a measured temperature in the measurement circuit according to Embodiment 2.

FIG. 8 is a graph showing an error of a resistance value of a measurement resistive element with respect to a measured temperature in the measurement circuit according to Embodiment 2.

FIG. 9 is a schematic circuit diagram of a measurement circuit according to Embodiment 3.

FIG. 10 is an explanatory view for explaining an example of currents flowing through the measurement circuit according to Embodiment 3.

FIG. 11 is a schematic circuit diagram of a measurement circuit according to Embodiment 4.

FIG. 12 is an explanatory view for explaining an example of currents flowing through the measurement circuit according to Embodiment 4.

FIG. 13 is an explanatory view for explaining an example of currents flowing through the measurement circuit according to Embodiment 4.

FIG. 14 is a graph showing a result of evaluation of the measurement circuit according to Embodiment 4.

FIG. 15 is a schematic circuit diagram of a first example of a voltage control circuit of a measurement circuit according to a modification.

FIG. 16 is a schematic circuit diagram of a second example of a voltage control circuit of a measurement circuit according to a modification.

### DETAILED DESCRIPTION OF THE DISCLOSURE

(1. Embodiments) Embodiments of the present disclosure are described below while referring to the drawings as needed. Note, however, that each of the embodiments below is an illustrative example for describing the present disclosure and is not intended to limit the present disclosure to the contents described below (e.g., shapes, dimensions, positions, and the like of constituent elements). Positional relationships such as vertical and horizontal directions are based on those illustrated in the drawings, unless otherwise specified. The drawings described in the embodiments below are schematic drawings, and ratios of sizes and thicknesses of constituent elements in the drawings do not necessarily reflect actual dimensional ratios. Furthermore, dimensional ratios of the elements are not limited to those illustrated in the drawings.

Note that in the following description, in a case where a plurality of constituent elements are distinguished, prefixes such as “first” and “second” are added to the names of the constituent elements. However, in a case where the constituent elements can be distinguished by reference signs given to the constituent elements, the prefixes such as “first” and “second” may be omitted in consideration of readability.

Note that in the following description, in a case where a plurality of constituent elements are distinguished, suffixes such as “−1” and “−2” are added to the reference signs of the constituent elements. However, in a case where the constituent elements are not distinguished, the suffixes such as “−1” and “−2” may be omitted in consideration of readability.

### 1.1 Embodiment 1

### 1.1.1 Configuration

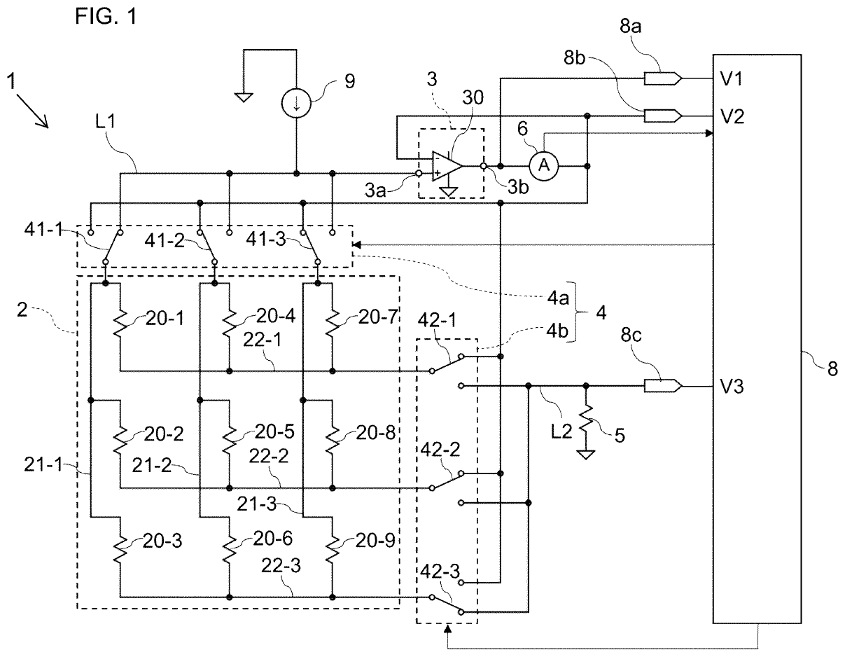

FIG. 1 is a schematic circuit diagram of a measurement circuit 1 according to Embodiment 1. The measurement circuit 1 is used to measure a physical quantity. In the present embodiment, the physical quantity measured by the measurement circuit 1 is a temperature. Although the temperature is not limited in particular, the temperature is, for example, a temperature of a human body, especially a temperature of a predetermined portion of a human body. The predetermined portion is an esophagus. The measurement circuit 1 is used to measure a temperature of a human esophagus.

The measurement circuit 1 includes a resistive element array 2, a voltage control circuit 3, a selection circuit 4, a reference resistive element 5, a current meter 6, a processing circuit 8, and a constant current source 9.

Furthermore, the measurement circuit 1 includes a first connection line L1 and a second connection line L2. The first connection line L1 is connected to the constant current source 9. A constant current is supplied from the constant current source 9 to the first connection line L1. The second connection line L2 is connected to the ground. In the present embodiment, in order that the resistive element array 2 can be placed in a human esophagus, the first connection line L1 and the second connection line L2 are configured so that distances of the resistive element array 2 to the constant current source 9 and the processing circuit 8 can be set to approximately 5 m.

The constant current source 9 is configured to output a constant current of a setting value. The constant current source 9 may be a conventionally known constant current source, and therefore detailed description thereof is omitted.

The resistive element array 2 is used to measure a physical quantity. The resistive element array 2 includes m first lines 21-1 to 21-3, n second lines 22-1 to 22-3, and a plurality of measurement resistive elements 20-1 to 20-9 where m and n are integers and satisfy m×n≥2. In the present embodiment, m=3, n=3, and m×n=9.

The m first lines 21-1 to 21-3 are independent of each other and are not connected to each other.

The n second lines 22-1 to 22-3 are independent of each other and are not connected to each other.

The plurality of measurement resistive elements 20-1 to 20-9 are arranged in a 3×3 array. Although a size of a region where the physical quantity can be measured by a single measurement resistive element 20 is limited, the physical quantity can be measured in a larger region by arranging a plurality of measurement resistive elements 20 in an array. In the present embodiment, reference resistance values of the plurality of measurement resistive elements 20 are equal. The reference resistance values are resistance values at a predetermined temperature. The predetermined temperature is, for example, 25° C.

The plurality of measurement resistive elements 20-1 to 20-9 are connected between the m first lines 21-1 to 21-3 and the n second lines 22-1 to 22-3. In the present embodiment, each of the plurality of measurement resistive elements 20-1 to 20-9 is connected between one of the m first lines 21-1 to 21-3 and one of the n second lines 22-1 to 22-3 so that the plurality of measurement resistive elements 20-1 to 20-9 correspond to different combinations of the m first lines 21-1 to 21-3 and the n second lines 22-1 to 22-3, respectively.

Specifically, first ends of the measurement resistive elements 20-1 to 20-3 are connected to the common first line 21-1, and second ends of the measurement resistive elements 20-1 to 20-3 are individually connected to the second lines 22-1 to 22-3. First ends of the measurement resistive elements 20-4 to 20-6 are connected to the common first line 21-2, and second ends of the measurement resistive elements 20-4 to 20-6 are individually connected to the second lines 22-1 to 22-3. First ends of the measurement resistive elements 20-7 to 20-9 are connected to the common first line 21-3, and second ends of the measurement resistive elements 20-7 to 20-9 are individually connected to the second lines 22-1 to 22-3.

Each of the measurement resistive elements 20 is a resistive element whose resistance value changes depending on the physical quantity to be measured. In the present embodiment, the physical quantity to be measured is a temperature, and the measurement resistive elements 20 is a thermistor. Examples of the thermistor include a negative temperature coefficient (NTC) thermistor, a positive temperature coefficient (PTC) thermistor, and a critical temperature resistor (CTR) thermistor, but the thermistor is not limited in particular.

The voltage control circuit 3 includes an input terminal 3a, an output terminal 3b, and an operational amplifier 30 located between the input terminal 3a and the output terminal 3b. The voltage control circuit 3 controls a voltage of the output terminal 3b by the operational amplifier 30 so that a difference between a voltage of the input terminal 3a and the voltage of the output terminal 3b is reduced. The input terminal 3a is connected to the first connection line L1. The voltage of the input terminal 3a corresponds to a voltage of the first connection line L1, that is, an output voltage of the constant current source 9. The output terminal 3b is connected to the processing circuit 8.

In the present embodiment, the voltage control circuit 3 is a voltage follower. In the voltage control circuit 3, the operational amplifier 30 includes a non-inverting input terminal, an inverting input terminal, and an output terminal, and the inverting input terminal and the output terminal are connected to each other. The non-inverting input terminal of the operational amplifier 30 is connected to the input terminal 3a of the voltage control circuit 3, and the output terminal of the operational amplifier 30 is connected to the output terminal 3b of the voltage control circuit 3.

The selection circuit 4 connects one of the m first lines 21-1 to 21-3 to the first connection line L1, connects one of the n second lines 22-1 to 22-3 to the second connection line L2 connected to the ground, and connects remaining lines among the m first lines 21-1 to 21-3 and the n second lines 22-1 to 22-3 to the output terminal 3b, and thereby can select a measurement resistive element 20 to which the constant current is supplied from among the plurality of measurement resistive elements 20-1 to 20-9.

In the present embodiment, the selection circuit 4 includes a first selection unit 4a and a second selection unit 4b.

The first selection unit 4a connects one of the m first lines 21-1 to 21-3 to the first connection line L1, and connects remaining lines among the m first lines 21-1 to 21-3 to the output terminal 3b. The first selection unit 4a includes a plurality of changeover switches 41-1 to 41-3 that are controllable. Each of the changeover switches 41-1 to 41-3 includes a common terminal, a first terminal, and a second terminal, and can be switched between a first state in which the common terminal is connected to the first terminal and a second state in which the common terminal is connected to the second terminal. The common terminals of the changeover switches 41-1 to 41-3 are connected to the first lines 21-1 to 21-3, respectively. The first terminals of the changeover switches 41-1 to 41-3 are connected to the first connection line L1. The second terminals of the changeover switches 41-1 to 41-3 are connected to the output terminal 3b.

The second selection unit 4b connects one of the n second lines 22-1 to 22-3 to the second connection line L2 and connects remaining lines among the n second lines 22-1 to 22-3 to the output terminal 3b. The second selection unit 4b includes a plurality of changeover switches 42-1 to 42-3 that are controllable. Each of the changeover switches 42-1 to 42-3 includes a common terminal, a first terminal, and a second terminal, and can be switched between a first state in which the common terminal is connected to the first terminal and a second state in which the common terminal is connected to the second terminal. The common terminals of the changeover switches 42-1 to 42-3 are connected to the second lines 22-1 to 22-3, respectively. The first terminals of the changeover switches 42-1 to 42-3 are connected to the second connection line L2. The second terminals of the changeover switches 42-1 to 42-3 are connected to the output terminal 3b.

The reference resistive element 5 is used to correct output of the resistive element array 2. The reference resistive element 5 is connected between the second connection line L2 and the ground. The reference resistive element 5 is a fixed resistive element. In a case where a resistance value of the reference resistive element 5 is too large as compared with the reference resistance values of the measurement resistive elements 20, it is difficult to obtain a sufficient voltage fluctuation amount relative to a change of the resistance values of the measurement resistive elements 20. Therefore, in the present embodiment, the resistance value of the reference resistive element 5 is smaller than the reference resistance values of the plurality of measurement resistive elements 20. It is desirable that the resistance value of the reference resistive element 5 be sufficiently lower than the reference resistance values of the measurement resistive elements 20. It is considered that a sufficient voltage fluctuation amount is obtained in a case where the resistance value of the reference resistive element 5 is equal to or less than 1/10 of the reference resistance values of the measurement resistive elements 20 although this depends on performance of an analog-digital converter circuit 8c, which will be described later, or required correction accuracy. Therefore, the resistance value of the reference resistive element 5 may be equal to or less than 1/10 of the reference resistance values of the plurality of measurement resistive elements 20.

The current meter 6 measures a current value of a current supplied from the output terminal 3b of the voltage control circuit 3. The current meter 6 includes a current measurement resistive element connected to the output terminal 3b of the voltage control circuit 3. In the current meter 6, a voltage between both ends of the current measurement resistive element indicates the current value of the current supplied from the output terminal 3b of the voltage control circuit 3.

The processing circuit 8 is a computer system including a processor and a memory as hardware, such as a System in Package (SiP). Examples of the processor include a semiconductor integrated circuit (IC), a large-scale integrated circuit (LSI), a field programmable gate array (FPGA) that is programed after manufacturing of an LSI, and an application specific integrated circuit (ASIC).

The processing circuit 8 is connected to the first selection unit 4a and the second selection unit 4b of the selection circuit 4 so that the processing circuit 8 can control the first selection unit 4a and the second selection unit 4b of the selection circuit 4.

The processing circuit 8 is connected to the output terminal 3b of the voltage control circuit 3 with an analog-digital converter circuit 8a interposed therebetween, and acquires a voltage (voltage value) V1 of the output terminal 3b of the voltage control circuit 3.

The processing circuit 8 is connected to the current meter 6 so as to be able to acquire a voltage between both ends of the current measurement resistive element of the current meter 6. In the present embodiment, the processing circuit 8 is connected to a low-voltage-side terminal of the current measurement resistive element with an analog-digital converter circuit 8b interposed therebetween, and acquires a voltage (voltage value) V2 of the low-voltage-side terminal. As illustrated in FIG. 1, not the voltage V1, but the voltage V2 is inputted to the inverting input terminal of the operational amplifier 30 of the voltage control circuit 3. Accordingly, the voltage V2 corresponds to the voltage of the first connection line L1.

The processing circuit 8 is connected to the second connection line L2 with the analog-digital converter circuit 8c interposed therebetween and acquires a voltage (voltage value) V3 of the second connection line L2.

The processing circuit 8 performs measurement processing for obtaining the resistance values of the plurality of measurement resistive elements 20-1 to 20-9 of the resistive element array 2. In the measurement processing, the resistance values of the plurality of measurement resistive elements 20-1 to 20-9 of the resistive element array 2 are obtained in order. For this purpose, the processing circuit 8 controls the selection circuit 4 to supply the constant current from the constant current source 9 to one of the plurality of measurement resistive elements 20-1 to 20-9.

In FIG. 1, the changeover switch 41-1 of the first selection unit 4a is in the first state, the changeover switches 41-2 and 41-3 of the first selection unit 4a are in the second state, the changeover switch 42-3 of the second selection unit 4b is in the first state, and the changeover switches 42-1 and 42-2 of the second selection unit 4b are in the second state. In this case, the constant current flows only through the measurement resistive element 20-3 connected between the first line 21-1 and the second line 22-3 among the plurality of measurement resistive elements 20-1 to 20-9 of the resistive element array 2.

V2−V3=I×Rv is satisfied where I is the setting value of the constant current of the constant current source 9 and Rv is the resistance value of the measurement resistive element 20. Although the constant current source 9 is configured to output the constant current of the setting value I, the current value of the constant current actually outputted from the constant current source 9 does not always match the setting value I due to various factors such as a surrounding environment. Therefore, to correctly measure the resistance value Rv of the measurement resistive element 20, it is desirable to perform correction in consideration of a fluctuation of the constant current of the constant current source 9, that is, shift of the actual current value of the constant current from the setting value I. A correction value for the constant current is expressed as Cal=I/I1 where I1 is the actual current value of the constant current of the constant current source 9.

In the present embodiment, the processing circuit 8 obtains a value indicative of the resistance value Rv of the measurement resistive element 20 to which the constant current is supplied on the basis of a difference between the voltage V2 of the first connection line L1 and the voltage V3 of the second connection line L2 and the correction value Cal for the constant current. The processing circuit 8 obtains Cal×(V2-V3) as the value indicative of the resistance value Rv of the measurement resistive element 20 to which the constant current is supplied. Cal×(V2-V3) corresponds to a voltage between both ends of the measurement resistive element 20 obtained when the constant current of the setting value I flows through the measurement resistive element 20.

The processing circuit 8 obtains the correction value Cal for the constant current on the basis of the setting value I of the constant current, a current value of a current flowing through the reference resistive element 5 determined by the voltage between both ends of the reference resistive element 5 (the voltage V3 of the second connection line L2) and the resistance value of the reference resistive element 5, and the current value measured by the current meter 6.

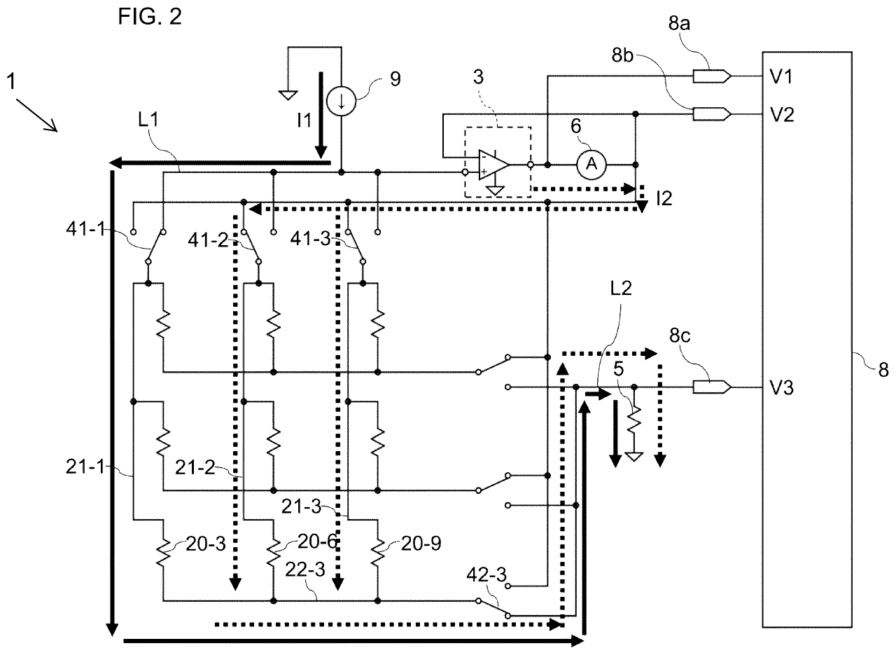

Next, a method for obtaining the correction value Cal is described with reference to FIG. 2. FIG. 2 is an explanatory view for explaining an example of currents flowing through the measurement circuit 1. In FIG. 2, the constant current flows through only the measurement resistive element 20-3 connected between the first line 21-1 and the second line 22-3 among the plurality of measurement resistive elements 20-1 to 20-9 of the resistive element array 2, as in FIG. 1. In FIG. 2, the reference signs of the constituent elements of the measurement circuit 1 are omitted as appropriate for clarity of illustration of the currents flowing through the measurement circuit 1. See FIG. 1 as for the reference signs omitted in FIG. 2.

I1 represents the actual current value of the constant current outputted from the constant current source 9. I2 represents a current value of the current outputted from the output terminal 3b of the voltage control circuit 3. The current outputted from the output terminal 3b of the voltage control circuit 3 is separated into a path of the changeover switch 41-2 and the first line 21-2 and a path of the changeover switch 41-3 and the first line 21-3, and then the separated currents merge and flow to the reference resistive element 5 through the second line 22-3 and the changeover switch 42-3. Accordingly, I1 is expressed by the following expression (1) where I5 is the current value of the current flowing through the reference resistive element 5.

$$I 1 = I 5 - I 2 \qquad ( 1 )$$

The current value I5 can be obtained on the basis of the resistance value of the reference resistive element 5 and the voltage V3 of the second connection line L2. I5 is expressed by the following expression (2) where R5 is the resistance value of the reference resistive element 5.

$$I 5 = \frac{V 3}{R 5} \qquad ( 2 )$$

The current value I2 can be obtained by using the current meter 6. A voltage difference between both ends of the current measurement resistive element of the current meter 6 is expressed by V1-V2. I2 is expressed by the following expression (3) where R6 is the resistance value of the current measurement resistive element.

$$I 2 = \frac{V 1 - V 2}{R 6} \qquad ( 3 )$$

The following expression (4) is obtained from the expressions (1) to (3).

$$I 1 = \frac{V 3}{R 5} - \frac{V 1 - V 2}{R 6} \qquad ( 4 )$$

The expression (4) can be deformed as indicated by the following expression (5).

$$I 1 = - \frac{1}{R 6} V 1 + \frac{1}{R 6} V 2 + \frac{1}{R 5} V 3 \qquad ( 5 )$$

I1 can be expressed by the following expression (6) on the basis of the expression (5) since the resistance value R5 of the reference resistive element 5 and the resistance value R6 of the current measurement resistive element are known. In the expression (6), α=−1/R6 and β=1/R5.

$$I 1 = α ( V 1 - V 2 ) + β V 3 \qquad ( 6 )$$

Therefore, the correction value Cal=I/I1 for the constant current is expressed by the following expression (7).

$$Cal = \frac{1}{α ( V 1 - V 2 ) + β V 3} \qquad ( 7 )$$

The processing circuit 8 obtains a value (=Cal×(V2−V3)) indicative of the resistance value Rv of each of the measurement resistive elements 20 of the resistive element array 2 by using the correction value Cal and obtains a temperature at each of the measurement resistive elements 20 on the basis of the value indicative of the resistance value Rv of each of the measurement resistive elements 20.

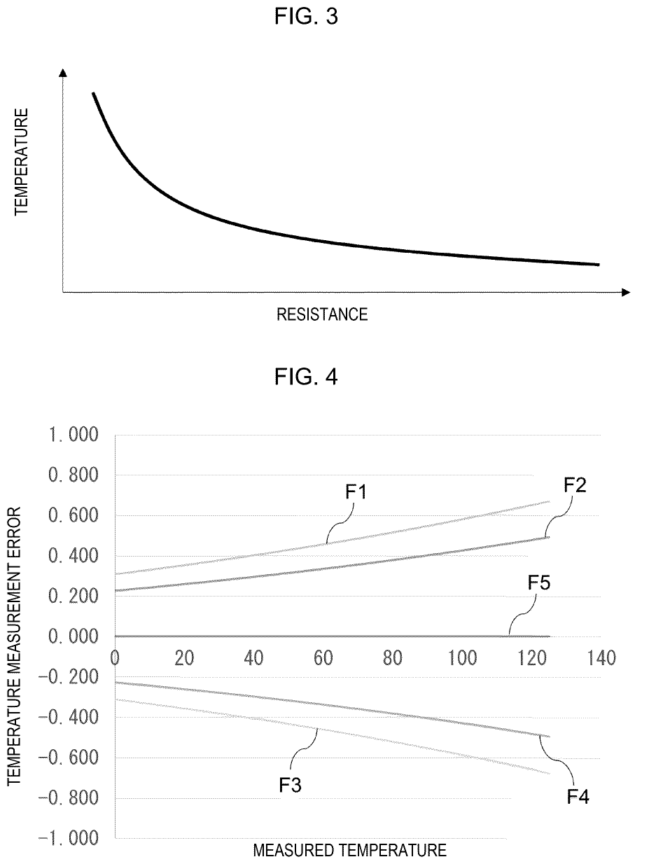

In the present embodiment, each of the measurement resistive elements 20 is a thermistor, and the thermistor is an element whose resistance value changes depending on a temperature, and a change of the temperature of the thermistor can be detected as a change of a voltage between both ends of the thermistor or a change of a current flowing through the thermistor by supplying a constant current or applying a constant voltage to the thermistor. FIG. 3 is a graph illustrating an example of resistance value-temperature characteristics of the measurement resistive elements 20. As is clear from FIG. 3, in the measurement resistive elements 20, the resistance value Rv decreases as the temperature increases.

Therefore, the temperature of the thermistor can be obtained on the basis of the voltage between both ends of the thermistor by obtaining an expression expressing voltage-temperature conversion in advance on the basis of resistance-temperature characteristics of the thermistor and a change of the voltage between both ends of the thermistor at the setting value I of the constant current of the constant current source 9. For example, the temperature T[° C.] of the thermistor T can be expressed by the following expression (8) where Vth is the voltage between both ends of the thermistor at the setting value I of the constant current of the constant current source 9. In the following expression (8), A and B are parameters. Specifically, the processing circuit 8 can obtain the temperature T of the measurement resistive element 20 by substituting Cal×(V2−V3) for Vth in the expression (8).

$$T = \frac{1}{A \times {log}_{e} V t h + B} - 273. 15 \qquad ( 8 )$$

The measurement circuit 1 described above uses the constant current from the constant current source 9 to obtain a value indicative of the resistance value Rv of each of the measurement resistive elements 20 of the resistive element array 2. That is, the voltage between both ends of each of the measurement resistive elements 20 is used to evaluate the resistance value Rv of each of the measurement resistive elements 20. Therefore, noise immunity and measurement accuracy can be improved as compared with a case where a constant voltage source is used to obtain the value indicative of the resistance value Rv of each of the measurement resistive elements 20 of the resistive element array 2. Furthermore, in a case where a thermistor is used in the configuration using a constant voltage source, a current flowing through the thermistor changes due to a change of a resistance value of the thermistor, and an amount of self-heating of the thermistor changes. This affects accuracy. In the present embodiment, use of the constant current source 9 makes it possible to control the current value to a constant current value and therefore control an amount of self-heating of the thermistor. As a result, measurement accuracy can be improved, and thermal runaway can be prevented.

In an actual use environment, due to the issues such as external noise, ambient temperature fluctuations, and aging-related degradation, measures such as imposing strict constraints on circuit scale or component tolerance ranges may be taken to design the constant current source 9 that always supplies a constant current with high accuracy. However, in the present embodiment, the processing circuit 8 obtains the value indicative of the resistance value Rv of each of the measurement resistive elements 20 of the resistive element array 2 by using the correction value Cal. Therefore, accurate measurement can be performed even in a case where the constant current from the constant current source 9 fluctuates.

### 1.1.2 Evaluation

Next, measurement accuracy was evaluated by simulation to confirm that measurement accuracy can be improved by the measurement circuit 1. In the simulation, a temperature measurement error of a measured temperature was obtained by changing an error of the constant current of the constant current source 9. The error of the constant current source 9 is an error relative to the setting value of the constant current of the constant current source 9. The error of the constant current source 9 is expressed as (I1−I)/I× 100 [%] where I1 is the actual current value of the constant current of the constant current source 9 and I is the setting value, as described above. Note that the simulation is intended to confirm that accurate measurement can be performed even in a case where the constant current from the constant current source 9 fluctuates, and therefore does not take an error of the measurement resistive element 20 into consideration.

FIG. 4 is a graph showing a result of the evaluation of the measurement circuit 1 according to Embodiment 1. In FIG. 4, the horizontal axis represents a measured temperature (a temperature of the measurement resistive element 20), and the vertical axis represents a temperature measurement error. F1 indicates a case where the error of the constant current source 9 was set to +0.5%, F2 indicates a case where the error of the constant current source 9 was set to +0.1%, F3 indicates a case where the error of the constant current source 9 was set to −0.5%, and F4 indicates a case where the error of the constant current source 9 as set to −0.1%. F5 indicates a case where correction was performed by using the correction value Cal in the case where the error of the constant current source 9 was set to +0.5%, +0.1%, −0.5%, or −0.1%. As is clear from FIG. 4, it was confirmed that the temperature measurement error was reduced by correction using the correction value Cal.

### 1.1.3 Effects and Others

The measurement circuit 1 described above includes the resistive element array 2 including the m first lines 21, the n second lines 22, and the plurality of measurement resistive elements 20 connected between the m first lines 21 and the n second lines 22 where m×n≥2; the voltage control circuit 3 that includes the input terminal 3a connected to the first connection line L1 to which the constant current is supplied from the constant current source 9, the output terminal 3b, and the operational amplifier 30 located between the input terminal 3a and the output terminal 3b and controls the voltage of the output terminal 3b by the operational amplifier 30 so that a difference between the voltage of the input terminal 3a and the voltage of the output terminal 3b is reduced; and the selection circuit 4 that connects one of the m first lines 21 to the first connection line L1, connects one of the n second lines 22 to the second connection line L2 connected to the ground, connects remaining lines among the m first lines 21 and the n second lines 22 to the output terminal 3b, and can thus select a measurement resistive element 20 to which the constant current is supplied from among the plurality of measurement resistive elements 20. This configuration can improve noise immunity and measurement accuracy.

The measurement circuit 1 further includes the reference resistive element 5 connected between the second connection line L2 and the ground and the current meter 6 that measures the current value I2 of the current supplied from the output terminal 3b. This configuration can improve measurement accuracy.

In the measurement circuit 1, the resistance value R5 of the reference resistive element 5 is smaller than the reference resistance values of the plurality of measurement resistive elements 20. This configuration can improve measurement accuracy.

In the measurement circuit 1, the resistance value R5 of the reference resistive element 5 is equal to or less than 1/10 of the reference resistance values of the plurality of measurement resistive elements 20. This configuration can improve measurement accuracy.

In the measurement circuit 1, the current meter 6 includes the current measurement resistive element connected to the output terminal 3b. This configuration can simplify the circuit configuration of the measurement circuit 1 and reduce a manufacturing cost.

The measurement circuit 1 further includes the processing circuit 8 that obtains the value indicative of the resistance value Rv of the measurement resistive elements 20 to which the constant current is supplied on the basis of the difference between the voltage V2 of the first connection line L1 and the voltage V3 of the second connection line L2 and the correction value Cal for the constant current. The correction value Cal for the constant current is obtained on the basis of the setting value I of the constant current, the current value I5 of the current flowing through the reference resistive element 5 determined by the voltage between both ends of the reference resistive element 5 (the voltage V3 of the second connection line L2) and the resistance value R5 of the reference resistive element 5, and the current value I2 measured by the current meter 6. This configuration can improve measurement accuracy.

The measurement circuit 1 further includes the constant current source 9. This configuration can improve measurement accuracy.

### 1.2 Embodiment 2

### 1.2.1 Configuration

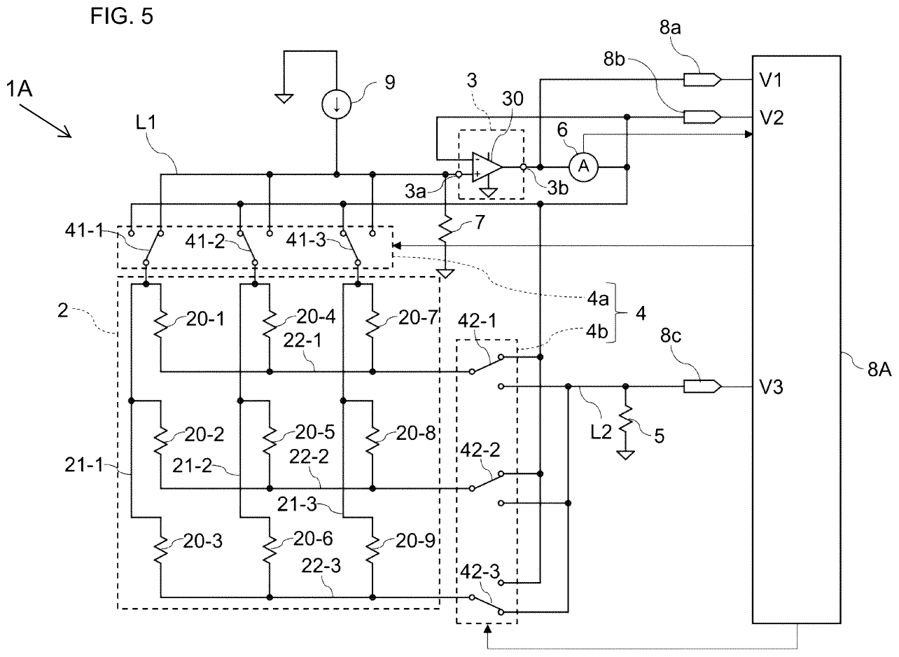

FIG. 5 is a schematic circuit diagram of a measurement circuit 1A according to Embodiment 2. The measurement circuit 1A includes a resistive element array 2, a voltage control circuit 3, a selection circuit 4, a reference resistive element 5, a current meter 6, a linearizing resistive element 7, a processing circuit 8A, and a constant current source 9.

The linearizing resistive element 7 is used to set a range of change in a voltage of a first connection line L1 with respect to a change of resistance values of measurement resistive elements 20 of the resistive element array 2 to a desired range. The linearizing resistive element 7 is connected to the first connection line L1 in parallel with the resistive element array 2. In the present embodiment, the linearizing resistive element 7 is directly connected to the ground. This can shorten a path between the linearizing resistive element 7 and the ground and can improve measurement accuracy. The linearizing resistive element 7 is a fixed resistive element. A resistance value of the linearizing resistive element 7 is set as appropriate with respect to reference resistance values of the measurement resistive elements 20.

The processing circuit 8A performs measurement processing as with the processing circuit 8, but does not use a correction value Cal unlike the processing circuit 8.

The processing circuit 8A obtains a resistance value Rv of each of the measurement resistive elements 20 of the resistive element array 2 and obtains a temperature at each of the measurement resistive elements 20 on the basis of the resistance value Rv of the measurement resistive element 20.

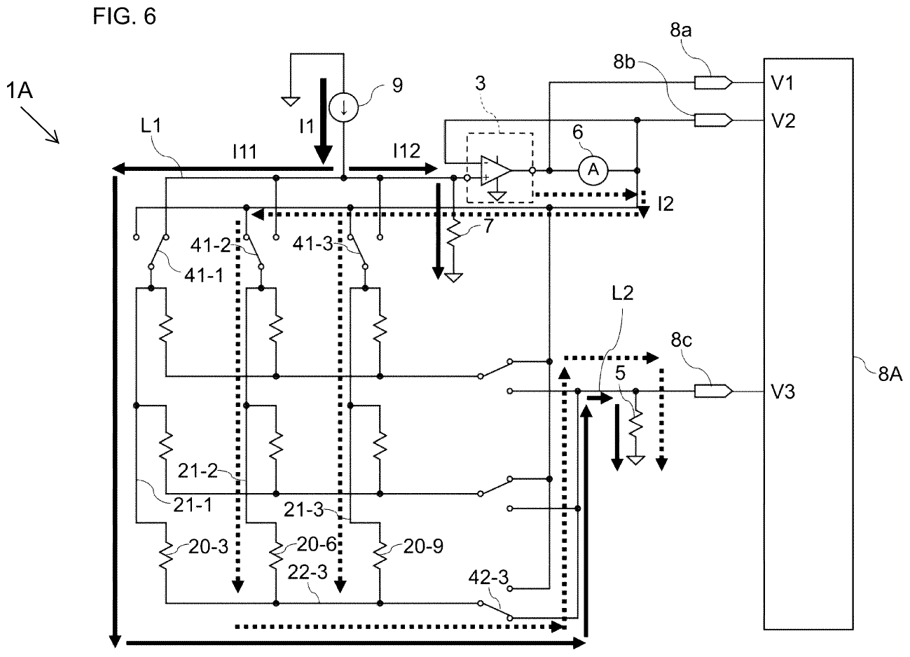

Next, a method for obtaining the resistance value Rv of the measurement resistive element 20 to which a constant current is supplied is described with reference to FIG. 6. FIG. 6 is an explanatory view for explaining an example of currents flowing through the measurement circuit 1A. In FIG. 6, the constant current flows through only a measurement resistive element 20-3 connected between a first line 21-1 and a second line 22-3 among the plurality of measurement resistive elements 20-1 to 20-9 of the resistive element array 2, as in FIG. 5. In FIG. 6, the reference signs of the constituent elements of the measurement circuit 1A are omitted as appropriate for clarity of illustration of the currents flowing through the measurement circuit 1A. See FIG. 5 as for the reference signs omitted in FIG. 6.

I1 represents an actual current value of the constant current outputted from the constant current source 9. I2 represents a current value of a current outputted from an output terminal 3b of the voltage control circuit 3.

The constant current outputted from the constant current source 9 is separated into a current flowing through the measurement resistive element 20 (20-3) and the reference resistive element 5 and a current flowing through the linearizing resistive element 7. I11 represents a current value of the current flowing through the measurement resistive element 20 (20-3). 112 represents a current value of the current flowing through the linearizing resistive element 7. I1 is expressed by the following expression (9).

$$I 1 = I 11 + I 12 \qquad ( 9 )$$

The current outputted from the output terminal 3b of the voltage control circuit 3 is separated into a path of a changeover switch 41-2 and a first line 21-2 and a path of a changeover switch 41-3 and a first line 21-3, and then the separated currents merge and reaches the second line 22-3. The second line 22-3 is connected to the ground with a changeover switch 42-3, a second connection line L2, and the reference resistive element 5 interposed therebetween. Accordingly, the current outputted from the output terminal 3b of the voltage control circuit 3 flows from the second line 22-3 to the reference resistive element 5.

The resistance value Rv of the measurement resistive element 20 is expressed by the following expression (10).

$$Rv = \frac{V 2 - V 3}{I 11} \qquad ( 10 )$$

In the reference resistive element 5, the current outputted from the output terminal 3b of the voltage control circuit 3 flows in the same direction as the constant current outputted from the constant current source 9. A current value I5 of the current flowing through the reference resistive element 5 is expressed by the following expression (11).

$$I 5 = I 11 + I 12 \qquad ( 11 )$$

The following expression (12) is obtained on the basis of the expressions (2) and (11).

$$I 11 + I 2 = \frac{V 3}{R 5} \qquad ( 12 )$$

I11 is expressed by the following expression (13) on the basis of the expressions (3) and (12).

$$I 11 = \frac{V 3}{R 5} - \frac{V 1 - V 2}{R 6} \qquad ( 13 )$$

Rv is expressed by the following expression (14) on the basis of the expressions (10) and (13).

$$R v = \frac{( V 2 - V 3 ) \times R 5 \times R 6}{V 3 \times R 6 - ( V 1 - V 2 ) \times R 5} \qquad ( 14 )$$

Since a resistance value R5 of the reference resistive element 5 and a resistance value R6 of the current measurement resistive element are already known, Rv can be obtained on the basis of V1, V2, and V3 acquired by the processing circuit 8.

A temperature of the measurement resistive element 20 can be obtained on the basis of the resistance value Rv of the measurement resistive element 20 by obtaining an expression expressing resistance-temperature conversion in advance on the basis of resistance-temperature characteristics of the measurement resistive element 20. For example, in a case where the temperature of the measurement resistive element 20 is T[° C.], a relationship between T and Rv is expressed by the following expression (15). In the expression (15), A, B, and C are parameters.

$$T = \frac{1}{A \times {log}_{e} \frac{R v}{B} + C} - 273.15 \qquad ( 15 )$$

The expression (14) does not include the actual current value I1 of the constant current of the constant current source 9. This indicates that Rv is not influenced by the constant current source 9. That is, influence of a fluctuation of the constant current of the constant current source 9 is removed by calculating Rv. The processing circuit 8A does not use a correction value for correcting the fluctuation of the constant current of the constant current source 9 to calculate Rv, unlike the processing circuit 8.

### 1.2.2 Evaluation

Next, measurement accuracy was evaluated by simulation to confirm that measurement accuracy can be improved by the measurement circuit 1A. In the simulation, an error of a difference between the voltage V2 of the first connection line L1 and the voltage V3 of the second connection line L2 with respect to a measured temperature and an error of the resistance value Rv of the measurement resistive element 20 with respect to the measured temperature were obtained by changing an error of the constant current of the constant current source 9. The error of the constant current source 9 is an error with respect to the setting value of the constant current of the constant current source 9. The error of the constant current source 9 is expressed by (I1−I)/I×100 [%] where I1 is the actual current value of the constant current of the constant current source 9 and I is the setting value, as described above. Note that the simulation is intended to confirm that accurate measurement can be performed even in a case where the constant current from the constant current source 9 fluctuates, and therefore does not take an error of the measurement resistive element 20 into consideration.

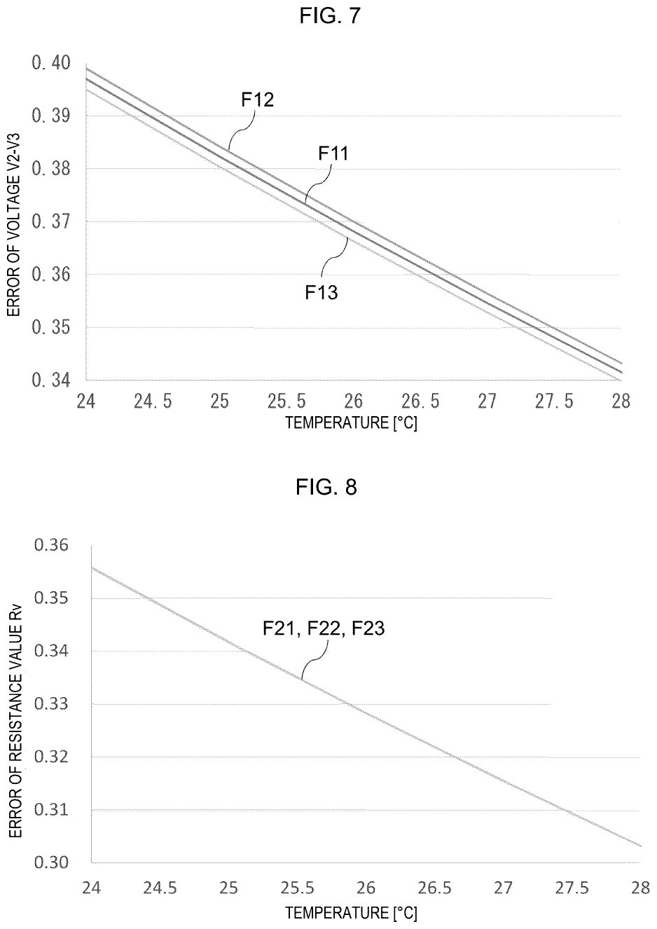

FIG. 7 is a graph showing an error of a difference between the voltage V2 of the first connection line L1 and the voltage V3 of the second connection line L2 with respect to a measured temperature. The horizontal axis represents the measured temperature (a temperature of the measurement resistive element 20), and the vertical axis represents the error of the difference between the voltage V2 of the first connection line L1 and the voltage V3 of the second connection line L2. F11 indicates a median (a case where the error of the constant current source 9 was set to 0.0%), F12 indicates a case where the error of the constant current source 9 was set to +0.5%, and F13 indicates a case where the error of the constant current source 9 was set to −0.5%. As is clear from FIG. 7, the error of the constant current source 9 is reflected in the difference between the voltage V2 of the first connection line L1 and the voltage V3 of the second connection line L2.

FIG. 8 is a graph showing an error of the resistance value Rv of the measurement resistive element 20 with respect to the measured temperature. The horizontal axis represents the measured temperature (the temperature of the measurement resistive elements 20), and the vertical axis represents the error of the resistance value Rv. F21 indicates a median (a case where the error of the constant current source 9 was set to 0.0%), F22 indicates a case where the error of the constant current source 9 was set to +0.5%, and F23 indicates a case where the error of the constant current source 9 was set to −0.5%. In FIGS. 8, F21, F22, and F23 match one another. Therefore, as is clear from FIG. 8, it was confirmed that the error of the constant current source 9 was reduced in a process of calculating the resistance value Rv.

### 1.2.3 Effects and Others

The measurement circuit 1A described above further includes the linearizing resistive element 7 connected to the first connection line L1 in parallel with the resistive element array 2. According to this configuration, a range of change in the voltage V2 of the first connection line L1 with respect to a change of the resistance value Rv of the measurement resistive element 20 can be set to a desired range.

In the measurement circuit 1A, the linearizing resistive element 7 is directly connected to the ground. This configuration can shorten a path between the linearizing resistive element 7 and the ground and can improve measurement accuracy.

The measurement circuit 1A further include the reference resistive element 5 connected between the second connection line L2 and the ground, the current meter 6 that measures the current value I2 of the current supplied from the output terminal 3b, and the processing circuit 8A. The processing circuit 8A obtains the resistance value Rv of the measurement resistive element 20 to which the constant current is supplied on the basis of the difference between the voltage V2 of the first connection line L1 and the voltage V3 of the second connection line L2, the current value I2 measured by the current meter 6, and the current value I5 of the current flowing through the reference resistive element 5 determined by the voltage between both ends of the reference resistive element 5 (the voltage V3 of the second connection line L2) and the resistance value R5 of the reference resistive element 5. This configuration can improve measurement accuracy.

### 1.3 Embodiment 3

### 1.3.1 Configuration

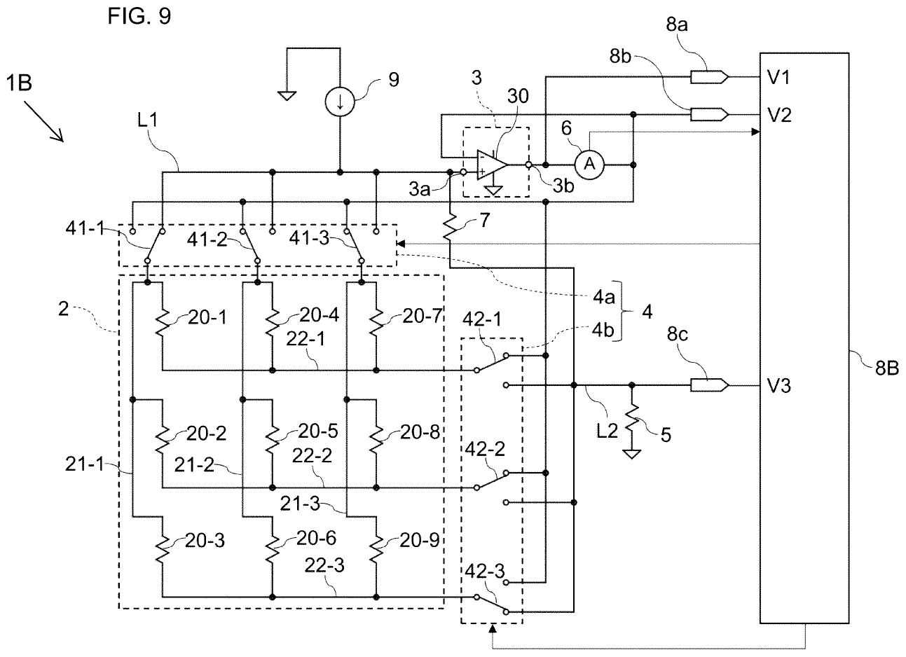

FIG. 9 s a schematic circuit diagram of a measurement circuit 1B according to Embodiment 3. The measurement circuit 1B includes a resistive element array 2, a voltage control circuit 3, a selection circuit 4, a reference resistive element 5, a current meter 6, a linearizing resistive element 7, a processing circuit 8B, and a constant current source 9.

In the measurement circuit 1B, the linearizing resistive element 7 is connected to a second connection line L2. The linearizing resistive element 7 is connected to the ground with the reference resistive element 5 interposed therebetween.

The processing circuit 8B performs measurement processing using a correction value Cal, as with the processing circuit 8.

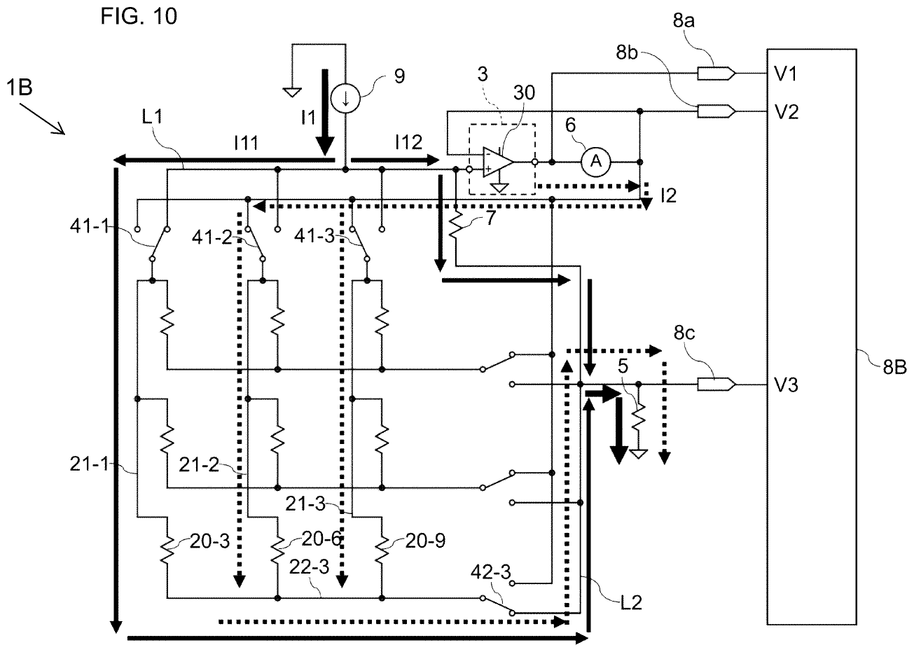

Next, a method for calculating the correction value Cal by the processing circuit 8B is described with reference to FIG. 10. FIG. 10 is an explanatory view for explaining an example of currents flowing through the measurement circuit 1B. In FIG. 10, a constant current flows through only a measurement resistive element 20-3 connected between a first line 21-1 and a second line 22-3 among a plurality of measurement resistive elements 20-1 to 20-9 of the resistive element array 2. In FIG. 10, the reference signs of the constituent elements of the measurement circuit 1B are omitted as appropriate for clarity of illustration of the currents flowing through the measurement circuit 1B. See FIG. 9 as for the reference signs omitted in FIG. 10.

As is clear from FIG. 10, the constant current outputted from the constant current source 9 is separated into a current flowing through the measurement resistive element 20 (20-3) and a current flowing through the linearizing resistive element 7, but the current flowing through the measurement resistive element 20 (20-3) and the current flowing through the linearizing resistive element 7 merge at the second connection line L2 and flow to the reference resistive element 5.

Therefore, a current value I5 of the current flowing through the reference resistive element 5 satisfies I5=I1+I2, and therefore I1=I5−I2 is satisfied. Therefore, in the present embodiment, I1 can be expressed by the above expression (6), and the correction value Cal=I/I1 for the constant current can be expressed by the above expression (7), as in Embodiment 1.

The measurement circuit 1B can set a range of change in a voltage V2 of the first connection line L1 with respect to a change of the resistance value Rv of the measurement resistive element 20 to a desired range by the linearizing resistive element 7, but the resistance value R7 of the linearizing resistive element 7 need not be considered in calculating the correction value Cal since the linearizing resistive element 7 is connected to the second connection line L2. This can make it easy to calculate the correction value Cal.

### 1.3.2 Evaluation

Next, measurement accuracy was evaluated by simulation to confirm that measurement accuracy can be improved by the measurement circuit 1B, and as a result, a result similar to the case of the measurement circuit 1 was obtained. It was confirmed that a temperature measurement error was reduced by correction using the correction value Cal also in the measurement circuit 1B.

### 1.3.3 Effects and Others

The measurement circuit 1B described above further includes the linearizing resistive element 7 connected to the first connection line L1 in parallel with the resistive element array 2. According to this configuration, a range of change in the voltage V2 of the first connection line L1 with respect to a change of the resistance value Rp of the measurement resistive element 20 can be set to a desired range.

In the measurement circuit 1B, the linearizing resistive element 7 is connected to the second connection line L2. This configuration can make it easy to calculate the correction value Cal.

The measurement circuit 1B further includes the reference resistive element 5 connected between the second connection line L2 and the ground, the current meter 6 that measures the current value I2 of the current supplied from the output terminal 3b, and the processing circuit 8B. The processing circuit 8B obtains a value indicative of the resistance value Rv of the measurement resistive element 20 to which the constant current is supplied on the basis of a difference between the voltage V2 of the first connection line L1 and the voltage V3 of the second connection line L2 and the correction value Cal for the constant current. The correction value Cal for the constant current is obtained on the basis of the setting value I of the constant current, the current value I5 of the current flowing through the reference resistive element 5 determined by a voltage between both ends of the reference resistive element 5 (the voltage V3 of the second connection line L2) and the resistance value R5 of the reference resistive element 5, and the current value I2 measured by the current meter 6. This configuration can improve measurement accuracy.

### 1.4 Embodiment 4

### 1.4.1 Configuration

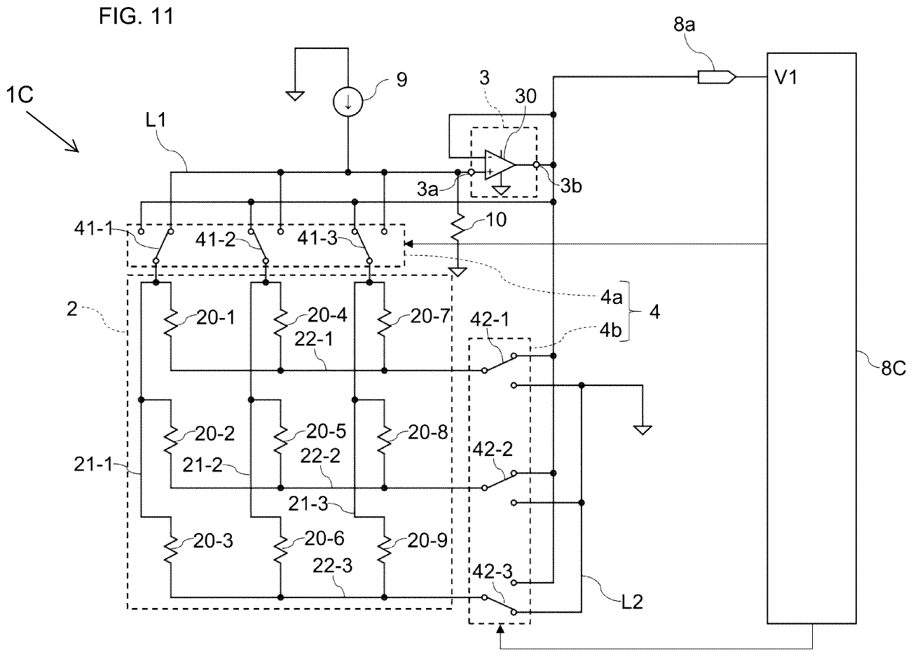

FIG. 11 is a schematic circuit diagram of a measurement circuit 1C according to Embodiment 4. The measurement circuit 1C includes a resistive element array 2, a voltage control circuit 3, a selection circuit 4, a processing circuit 8C, a constant current source 9, and a correction resistive element 10. The measurement circuit 1C does not include a reference resistive element 5, and a second connection line L2 is directly connected to the ground, unlike the measurement circuits 1, 1A, and 1B.

The correction resistive element 10 is a linearizing resistive element connected to a first connection line L1 in parallel with the resistive element array 2. This makes it possible to set a range of change in a voltage of the first connection line L1 with respect to a change of resistance values of measurement resistive elements 20 of the resistive element array 2 to a desired range. In the present embodiment, the correction resistive element 10 is directly connected to the ground. This can shorten a path between the correction resistive element 10 and the ground and can improve measurement accuracy. The correction resistive element 10 is a fixed resistive element. A resistance value of the correction resistive element 10 is set as appropriate with respect to reference resistance values of the measurement resistive elements 20.

The processing circuit 8C is connected to an output terminal 3b of the voltage control circuit 3 with an analog-digital converter circuit 8a interposed therebetween, and acquires a voltage (voltage value) V1 of the output terminal 3b of the voltage control circuit 3. As illustrated in FIG. 11, the voltage V1 is inputted to an inverting input terminal of an operational amplifier 30 of the voltage control circuit 3. Therefore, the voltage V1 of the output terminal 3b corresponds to the voltage of the first connection line L1.

The measurement circuit 1C obtains a value indicative of a resistance value Rv of a measurement resistive element 20 to which a constant current is supplied on the basis of the voltage V1 of the first connection line L1 (the voltage of the output terminal 3b) and a correction value Cal for the constant current. In the present embodiment, measurement processing includes first processing for obtaining the correction value Cal and second processing for obtaining the voltage V1 of the first connection line L1 corresponding to the measurement resistive element 20 to which the constant current is supplied.

In the first processing, the processing circuit 8C obtains the correction value for the constant current on the basis of a current value of a current flowing through the correction resistive element 10 determined by a voltage between both ends of the correction resistive element 10 and a resistance value of the correction resistive element 10 obtained in a state in which none of the m first lines 21 is connected to the first connection line L1 and a setting value I of the constant current.

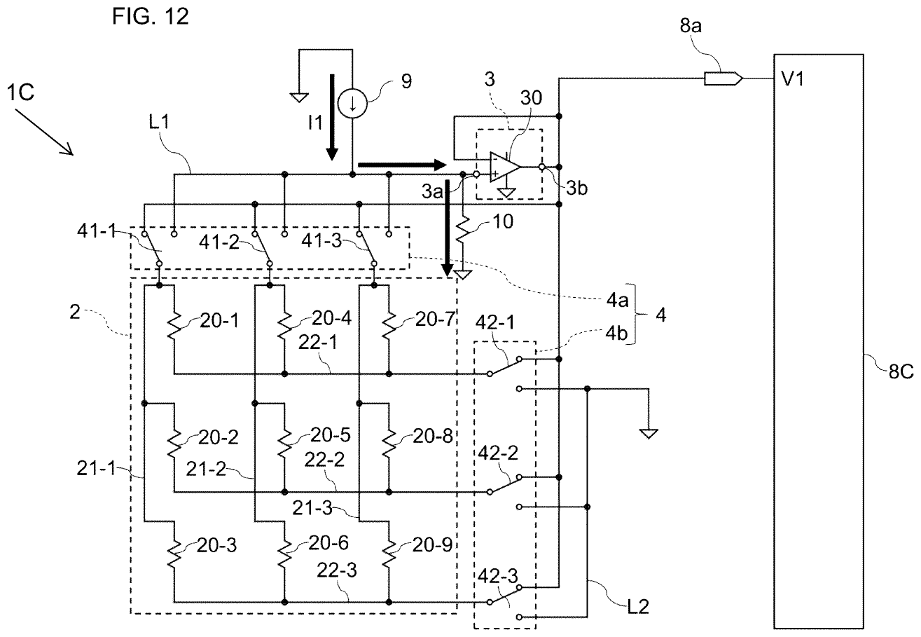

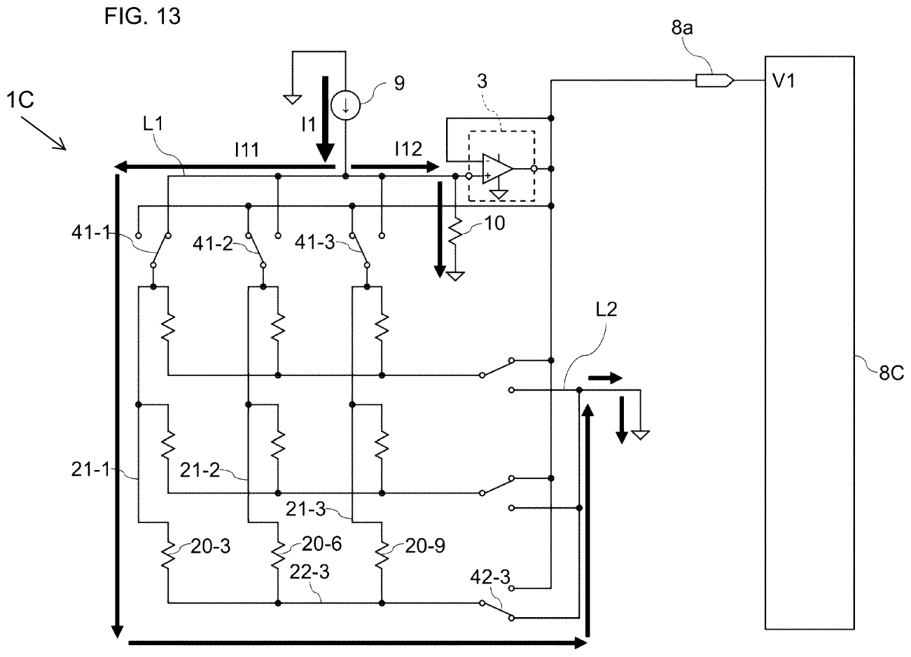

A method for obtaining the correction value Cal by the processing circuit 8C in the first processing is described with reference to FIGS. 12 and 13. FIG. 12 is an explanatory view for explaining an example of currents flowing through the measurement circuit 1C in the first processing. In FIG. 12, each of changeover switches 41-1 to 41-3 of a first selection unit 4a is in a second state, and each of changeover switches 42-1 to 42-3 of a second selection unit 4b is in the second state. In this case, the constant current flows through none of the plurality of measurement resistive elements 20-1 to 20-9 of the resistive element array 2. In FIG. 12, the reference signs of the constituent elements of the measurement circuit 1C are omitted as appropriate for clarity of illustration of the currents flowing through the measurement circuit 1C. See FIG. 11 as for the reference signs omitted in FIG. 12.

As is clear from FIG. 12, the constant current outputted from the constant current source 9 flows through only the correction resistive element 10. Therefore, a current value I1 of the constant current outputted from the constant current source 9 is expressed by the following expression (16) where R10 is the resistance value of the correction resistive element 10.

$$I 1 = \frac{V 1}{R 10} \qquad ( 16 )$$

Since the resistance value R10 of the correction resistive element 10 is already known, I1 can be expressed by the following expression (17) on the basis of the expression (16). In the expression (17), α=1/R10.

$$I 1 = α \times V 1 \qquad ( 17 )$$

Therefore, the correction value Cal=I/I1 for the constant current is expressed by the following expression (18).

$$Cal = \frac{I}{α \times V 1} \qquad ( 18 )$$

In the second processing, the processing circuit 8C controls the selection circuit 4 to supply the constant current from the constant current source 9 to one of the plurality of measurement resistive elements 20-1 to 20-9 and acquires the voltage V1 of the output terminal 3b of the voltage control circuit 3.

FIG. 13 is an explanatory view for explaining an example of currents flowing through the measurement circuit 1C in the second processing. In FIG. 13, the changeover switch 41-1 of the first selection unit 4a is in a first state, the changeover switches 41-2 and 41-3 of the first selection unit 4a are in the second state, the changeover switch 42-3 of the second selection unit 4b is in a first state, the changeover switches 42-1 and 42-2 of the second selection unit 4b are in the second state, and the constant current flows only through the measurement resistive element 20-3 connected between a first line 21-1 and a second line 22-3 among the plurality of measurement resistive elements 20-1 to 20-9 of the resistive element array 2. In FIG. 13, the reference signs of the constituent elements of the measurement circuit 1C are omitted as appropriate for clarity of illustration of the currents flowing through the measurement circuit 1C. See FIG. 11 as for the reference signs omitted in FIG. 13.

As is clear from FIG. 13, the constant current outputted from the constant current source 9 is separated into a current flowing through the measurement resistive element 20 (20-3) and a current flowing through the correction resistive element 10. The processing circuit 8C thus acquires the voltage V1 of the output terminal 3b of the voltage control circuit 3 regarding the measurement resistive element 20 through which the constant current from the constant current source 9 flows.

In the present embodiment, the measurement resistive elements 20 and the correction resistive element 10 are connected to the first connection line L1 in parallel with each other. The voltage V1 of the output terminal 3b is expressed by the following expression (19) on the basis of a combined resistance value combining the resistance value Rv of the measurement resistive element 20 and the resistance value R10 of the correction resistive element 10 and the current value I1 of the constant current from the constant current source 9.

$$V 1 = \frac{R v + R 10}{Rv \times R 7} \times I 1 \qquad ( 19 )$$

A temperature of the measurement resistive element 20 can be obtained on the basis of the voltage V1 of the output terminal 3b by obtaining an expression expressing voltage-temperature conversion in advance on the basis of resistance-temperature characteristics of the measurement resistive element 20 and a change of the voltage V1 of the output terminal 3b at the setting value I of the constant current of the constant current source 9. For example, T can be expressed by the following expression (20) where T represents the temperature of the measurement resistive element 20. In the following expression (20), A, B, C, D, E, and F are parameters.

$$T = A \times V {1}^{5} + B \times V {1}^{4} + C \times V {1}^{3} + D \times V {1}^{2} + E \times V 1 + F \qquad ( 20 )$$

The measurement circuit 1C obtains a value of the resistance value Rv of the measurement resistive element 20 to which the constant current is supplied on the basis of the correction value Cal for the constant current obtained in the first processing and the voltage V1 of the first connection line L1 obtained in the second processing. The measurement circuit 1C uses Cal×V1 as the value indicative of the resistance value Rv of the measurement resistive element 20 to which the constant current is supplied.

The measurement circuit 1C may alternately perform the first processing and the second processing while changing the measurement resistive element 20 to which the constant current is supplied. However, in a case where the fluctuation of the constant current is considered to be small, the first processing may be performed every time the second processing is performed plural times while changing the measurement resistive element 20 to which the constant current is supplied or the first processing may be performed before or after the second processing is performed on all of the measurement resistive elements 20. A period for the whole measurement processing can be shortened by reducing the number of times of execution of the first processing.

### 1.4.2 Evaluation

Next, measurement accuracy was evaluated by simulation to confirm that measurement accuracy can be improved by the measurement circuit 1C. The simulation was performed by using a method similar to that of Embodiment 1.

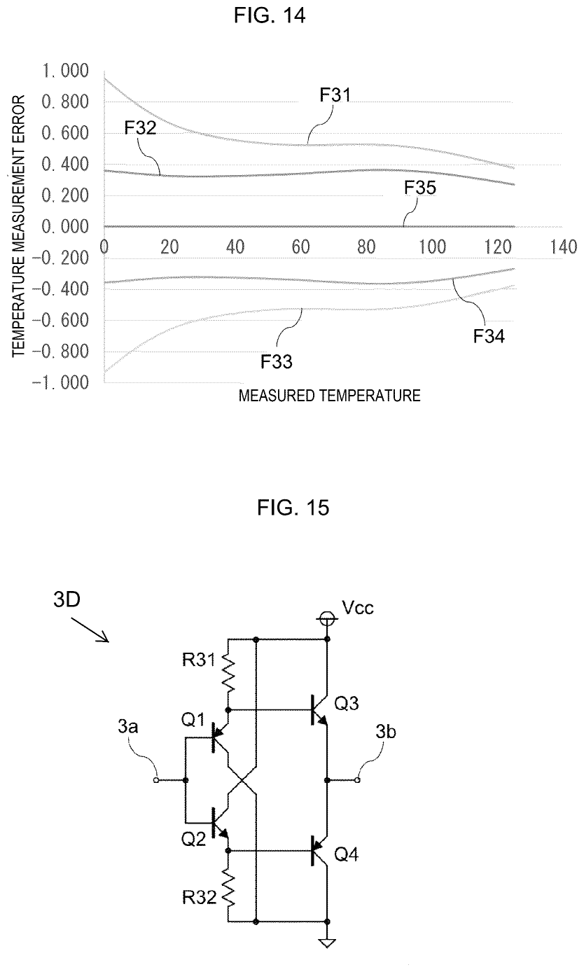

FIG. 14 is a graph showing a result of evaluation of the measurement circuit 1C according to Embodiment 4. In FIG. 14, the horizontal axis represents a measured temperature (the temperature of the measurement resistive element 20), and the vertical axis represents a temperature measurement error. F31 indicates a case where an error of the constant current source 9 was set to +0.5%, F32 indicates a case where the error of the constant current source 9 was set to +0.1%, F33 indicates a case where the error of the constant current source 9 was set to −0.5%, and F34 indicates a case where the error of the constant current source 9 was set to −0.1%. F35 indicates a case where correction is performed by using the correction value Cal in the case where the error of the constant current source 9 was set to +0.5%, +0.1%, −0.5%, or −0.1%. As is clear from FIG. 14, it was confirmed that the temperature measurement error was reduced by correction using the correction value Cal.

### 1.4.3 Effects and Others

The measurement circuit 1C described above further includes the correction resistive element 10 connected to the first connection line L1 in parallel with the resistive element array 2 and the processing circuit 8C that obtains a value indicative of the resistance value Rv of the measurement resistive element 20 to which the constant current is supplied on the basis of the voltage V1 of the first connection line L1 and the correction value Cal for the constant current. The processing circuit 8C obtains the correction value Cal for the constant current on the basis of the current value of the current flowing through the correction resistive element 10 determined by the voltage between both ends of the correction resistive element 10 (the voltage V1 of the first connection line L1) and the resistance value R10 of the correction resistive element 10 obtained in a state where none of the m first lines 21 is connected to the first connection line L1 and the setting value I of the constant current. This configuration can improve measurement accuracy.

In the measurement circuit 1C, the correction resistive element 10 is a linearizing resistive element connected in parallel with the resistive element array 2. According to this configuration, a range of change in the voltage of the first connection line L1 with respect to a change of the resistance values of the measurement resistive elements 20 can be set to a desired range.

In the measurement circuit 1C, the second connection line L2 is directly connected to the ground. This configuration can simplify the circuit configuration of the measurement circuit 1C and reduce a manufacturing cost.

### 2. Modification

Embodiments of the present disclosure are not limited to the above embodiments. The above embodiments can be changed in various ways in accordance with design needs or the like, provided that the possible benefit of the present disclosure can be accomplished. Modifications of the above embodiments are listed below. The modifications described below can be combined as appropriate.

In the following description, although the configurations described below may be applicable to any of Embodiments 1 to 4, reference numerals used in Embodiment 1 are referred to for the sake of simplicity. This does not imply any exclusion of applicability to Embodiments 2 through 4.

In one modification, the configuration of the resistive element array 2 is not limited in particular. The number, layout, and the like of the measurement resistive elements 20 may be set as appropriate in accordance with a measurement target. The measurement resistive elements 20 are not limited to thermistors, and may be resistive elements whose resistance values change in accordance with a target physical quantity, such as resistive elements whose resistance values change in accordance with mechanical modification such as vibration or distortion. The number of first lines 21 may be one or more and the number of second lines 22 may be one or more, but a situation where both of the number of first lines 21 and the number of second lines 22 are one may be avoided.

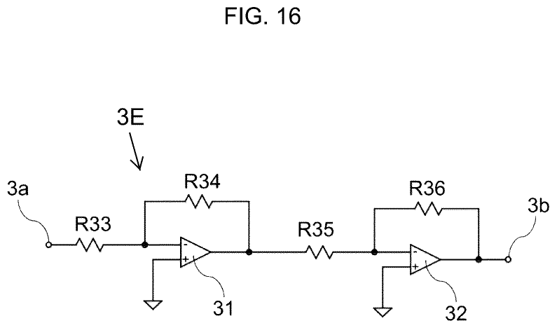

In one modification, the configuration of the voltage control circuit 3 is not limited in particular. It is sufficient that the voltage control circuit 3 be configured to control the voltage of the output terminal 3b by an operational amplifier and/or a transistor located between the input terminal 3a and the output terminal 3b so that a difference between the voltage of the input terminal 3a and the voltage of the output terminal 3b is reduced. FIGS. 15 and 16 illustrate voltage control circuits 3D and 3E of measurement circuits according to modifications.

As illustrated in FIG. 15, the voltage control circuit 3D is a buffer circuit using a transistor. The buffer circuit of FIG. 15 is also called a diamond buffer circuit. The voltage control circuit 3D includes an input terminal 3a, an output terminal 3b, and transistors Q1 to Q4 located between the input terminal 3a and the output terminal 3b. The voltage control circuit 3D controls the voltage of the output terminal 3b by the transistors Q1 to Q4 so that a difference between the voltage of the input terminal 3a and the voltage of the output terminal 3b is reduced. More specifically, the voltage control circuit 3D includes the four transistors Q1 to Q4 and resistors R31 and 32. The transistors Q1 and Q4 are PNP bipolar transistors, and the transistors Q2 and Q3 are NPN bipolar transistors. In the transistor Q1, an emitter is connected to an internal power source Vcc with the resistor R31 interposed therebetween, a collector is connected to the ground, and a base is connected to the input terminal 3a. In the transistor Q2, a collector is connected to the internal power source Vcc, an emitter is connected to the ground with the resistor R32 interposed therebetween, and a base is connected to the input terminal 3a. In the transistor Q3, a collector is connected to the internal power source Vcc, an emitter is connected to the output terminal 3b, and a base is connected between the emitter of the transistor Q1 and the resistor R31. In the transistor Q4, an emitter is connected to the output terminal 3b, a collector is connected to the ground, and a base is connected between the emitter of the transistor Q2 and the resistor R32.

As illustrated in FIG. 16, the voltage control circuit 3E is an amplifier circuit with a gain of one. The voltage control circuit 3E includes an input terminal 3a, an output terminal 3b, and operational amplifiers 31 and 32 located between the input terminal 3a and the output terminal 3b. The voltage control circuit 3E controls the voltage of the output terminal 3b by the operational amplifiers 31 and 32 so that a difference between the voltage of the input terminal 3a and the voltage of the output terminal 3b is reduced. More specifically, the voltage control circuit 3E includes the operational amplifiers 31 and 32 and resistor R33 to R36. In the operational amplifier 31, a non-inverting input terminal is connected to the ground, an inverting input terminal is connected to the input terminal 3a with the resistor R33 interposed therebetween, and an output terminal is connected to the inverting input terminal with the resistor R34 interposed therebetween. In the operational amplifier 32, a non-inverting input terminal is connected to the ground, an inverting input terminal is connected to the output terminal of the operational amplifier 31 with the resistor R35 interposed therebetween, and an output terminal is used as the output terminal 3b of the voltage control circuit 3E and is connected to the inverting input terminal with the resistor R36 interposed therebetween.

In one modification, the configuration of the selection circuit 4 is not limited in particular. It is sufficient that the selection circuit 4 be able to selectively supply the constant current to any number of measurement resistive elements 20 among the plurality of measurement resistive elements 20 of the resistive element array 2.

In one modification, the reference resistive element 5 may be a single resistive element or may be a circuit including a plurality of resistive elements. The reference resistive element 5 is not essential and can be omitted.

In one modification, the current meter 6 is not limited to the configuration including a current measurement resistive element and may be a conventionally known configuration such as a current transformer.

In one modification, the linearizing resistive element 7 may be a single resistive element or may be a circuit including a plurality of resistive elements. The linearizing resistive element 7 is not essential and can be omitted.

In one modification, the correction resistive element 10 need not always be connected to the first connection line L1, and may be configured to be connectable to the first connection line L1 when the resistive element array 2 is isolated from the first connection line L1. The “connectable” means that the correction resistive element 10 may be separable from the first connection line L1 by a switch or the like. For example, the correction resistive element 10 may be connected to the first connection line L1 with a switch interposed therebetween, and the switch may be turned on in the first processing and may be turned off in the second processing.

### 3. Aspects

As is clear from the above embodiments and modifications, the present disclosure encompasses the following aspects.

### (Aspect 1)

A measurement circuit including: a resistive element array including m first lines, n second lines, and a plurality of measurement resistive elements connected between the m first lines and the n second lines where m×n≥2; a voltage control circuit including an input terminal connected to a first connection line to which a constant current is supplied from a constant current source, an output terminal, and an operational amplifier and/or a transistor located between the input terminal and the output terminal, and controls a voltage of the output terminal by the operational amplifier and/or the transistor so that a difference between a voltage of the input terminal and the voltage of the output terminal is reduced; and a selection circuit that connects one of the m first lines to the first connection line, connects one of the n second lines to a second connection line connected to ground, and connects remaining lines among the m first lines and the n second lines to the output terminal, and is thereby capable of selecting a measurement resistive element to which the constant current is supplied from among the plurality of measurement resistive elements.

### (Aspect 2)

The measurement circuit according to aspect 1, further including: a reference resistive element connected between the second connection line and the ground; and a current meter that measures a current value of a current supplied from the output terminal.

### (Aspect 3)

The measurement circuit according to aspect 2, in which a resistance value of the reference resistive element is smaller than reference resistance values of the plurality of measurement resistive elements.

### (Aspect 4)

The measurement circuit according to aspect 3, in which the resistance value of the reference resistive element is equal to or less than 1/10 of the reference resistance values of the plurality of measurement resistive elements.

### (Aspect 5)

The measurement circuit according to any one of aspects 2 to 4, in which the current meter includes a current measurement resistive element connected to the output terminal.

### (Aspect 6)

The measurement circuit according to any one of aspects 2 to 5, further including a processing circuit that obtains a value indicative of a resistance value of a measurement resistive element to which the constant current is supplied on the basis of a difference between a voltage of the first connection line and a voltage of the second connection line and a correction value for the constant current, in which the correction value for the constant current is obtained on the basis of a setting value of the constant current, a current value of a current flowing through the reference resistive element determined by a voltage between both ends of the reference resistive element and a resistance value of the reference resistive element, and the current value measured by the current meter.

### (Aspect 7)

The measurement circuit according to aspect 1, further including a linearizing resistive element connected to the first connection line in parallel with the resistive element array.

### (Aspect 8)

The measurement circuit according to aspect 7, in which the linearizing resistive element is directly connected to the ground.

### (Aspect 9)

The measurement circuit according to aspect 8, further including: a reference resistive element connected between the second connection line and the ground; a current meter that measures a current value of a current supplied from the output terminal; and a processing circuit that obtains a resistance value of a measurement resistive element to which the constant current is supplied on the basis of a difference between a voltage of the first connection line and a voltage of the second connection line, the current value measured by the current meter, and a current value of a current flowing through the reference resistive element determined by a voltage between both ends of the reference resistive element and a resistance value of the reference resistive element.

### (Aspect 10)

The measurement circuit according to aspect 7, in which the linearizing resistive element is connected to the second connection line.

### (Aspect 11)

The measurement circuit according to aspect 10, further including: a reference resistive element connected between the second connection line and the ground; a current meter that measures a current value of a current supplied from the output terminal; and a processing circuit that obtains a value indicative of a resistance value of a measurement resistive element to which the constant current is supplied on the basis of a difference between a voltage of the first connection line and a voltage of the second connection line and a correction value for the constant current, in which the correction value for the constant current is obtained on the basis of a setting value of the constant current, a current value of a current flowing through the reference resistive element determined by a voltage between both ends of the reference resistive element and a resistance value of the reference resistive element, and the current value measured by the current meter.

### (Aspect 12)

The measurement circuit according to aspect 1, further including: a correction resistive element that is connectable to the first connection line in parallel with the resistive element array; and a processing circuit that obtains a value indicative of a resistance value of a measurement resistive element to which the constant current is supplied on the basis of a voltage of the first connection line and a correction value for the constant current, in which the processing circuit obtains the correction value for the constant current on the basis of a current value of a current flowing through the correction resistive element determined by a voltage value of a voltage between both ends of the correction resistive element and a resistance value of the correction resistive element obtained in a state where none of the m first lines is connected to the first connection line and a setting value of the constant current.

### (Aspect 13)

The measurement circuit according to aspect 12, in which the correction resistive element is a linearizing resistive element connected in parallel with the resistive element array.

### (Aspect 14)

The measurement circuit according to aspect 12 or 13, in which the second connection line is directly connected to the ground.

### (Aspect 15)

The measurement circuit according to any one of aspects 1 to 14, further including the constant current source.

The aspects 2 to 15 are optional elements and are not essential.

The present disclosure is applicable to a measurement circuit. Specifically, the present disclosure is applicable to a measurement circuit including a resistive element array.
1, 1A, 1B, 1C measurement circuit
2 resistive element array
20 measurement resistive element
21 first line
22 second line
3, 3D, 3E voltage control circuit
3a input terminal
3b output terminal
4 selection circuit
5 reference resistive element
6 current meter
7 linearizing resistive element
8, 8A, 8B, 8C processing circuit
9 constant current source
10 correction resistive element

1. A measurement circuit comprising:
a resistive element array including m first lines, n second lines, and a plurality of measurement resistive elements connected between the m first lines and the n second lines where m×n≥2;
a voltage control circuit comprising:
an input terminal connected to a first connection line to which a constant current is supplied from a constant current source,
an output terminal, and
an operational amplifier or a transistor located between the input terminal and the output terminal, the voltage control circuit being configured to control a voltage of the output terminal by the operational amplifier or the transistor such that a difference between a voltage of the input terminal and the voltage of the output terminal is reduced; and
a selection circuit configured to connect one of the m first lines to the first connection line, connect one of the n second lines to a second connection line connected to ground, and connect remaining lines among the m first lines and the n second lines to the output terminal, so as to select a measurement resistive element to which the constant current is supplied.

2. The measurement circuit according to claim 1, further comprising:
a reference resistive element connected between the second connection line and ground; and
a current meter configured to measure a current value of a current supplied from the output terminal.

3. The measurement circuit according to claim 2, wherein a resistance value of the reference resistive element is smaller than reference resistance values of the plurality of measurement resistive elements.

4. The measurement circuit according to claim 3, wherein the resistance value of the reference resistive element is equal to or less than 1/10 of the reference resistance values of the plurality of measurement resistive elements.

5. The measurement circuit according to claim 2, wherein the current meter comprises a current measurement resistive element connected to the output terminal.

6. The measurement circuit according to claim 2, further comprising:
a processing circuit configured to obtain a value indicative of a resistance value of a measurement resistive element to which the constant current is supplied based on a difference between a voltage of the first connection line and a voltage of the second connection line, and a correction value for the constant current,
wherein the correction value for the constant current is obtained based on a setting value of the constant current, a current value of a current flowing through the reference resistive element determined by a voltage between both ends of the reference resistive element and a resistance value of the reference resistive element, and the current value measured by the current meter.

7. The measurement circuit according to claim 1, further comprising:
a linearizing resistive element connected to the first connection line in parallel with the resistive element array.

8. The measurement circuit according to claim 7, wherein the linearizing resistive element is directly connected to ground.

9. The measurement circuit according to claim 8, further comprising:
a reference resistive element connected between the second connection line and ground;
a current meter configured to measure a current value of a current supplied from the output terminal; and
a processing circuit configured to obtain a resistance value of a measurement resistive element to which the constant current is supplied based on a difference between a voltage of the first connection line and a voltage of the second connection line, the current value measured by the current meter, and a current value of a current flowing through the reference resistive element determined by a voltage between both ends of the reference resistive element and a resistance value of the reference resistive element.

10. The measurement circuit according to claim 7, wherein the linearizing resistive element is connected to the second connection line.

11. The measurement circuit according to claim 10, further comprising:
a reference resistive element connected between the second connection line and the ground;
a current meter configured to measure a current value of a current supplied from the output terminal; and
a processing circuit configured to obtain a value indicative of a resistance value of a measurement resistive element to which the constant current is supplied based on a difference between a voltage of the first connection line and a voltage of the second connection line, and a correction value for the constant current,
wherein the correction value for the constant current is obtained based on a setting value of the constant current, a current value of a current flowing through the reference resistive element determined by a voltage between both ends of the reference resistive element and a resistance value of the reference resistive element, and the current value measured by the current meter.

12. The measurement circuit according to claim 1, further comprising:
a correction resistive element that is connected to the first connection line in parallel with the resistive element array; and
a processing circuit configured to obtain a value indicative of a resistance value of a measurement resistive element to which the constant current is supplied on a basis of a voltage of the first connection line and a correction value for the constant current,
wherein the processing circuit is configured to obtain the correction value for the constant current based on a current value of a current flowing through the correction resistive element determined by a voltage value of a voltage between both ends of the correction resistive element and a resistance value of the correction resistive element obtained in a state where none of the m first lines is connected to the first connection line and a setting value of the constant current.

13. The measurement circuit according to claim 12, wherein the correction resistive element is a linearizing resistive element connected in parallel with the resistive element array.

14. The measurement circuit according to claim 12, wherein the second connection line is directly connected to the ground.

15. The measurement circuit according to claim 1, further comprising:
the constant current source.
